(19) United States
(12) Patent Application Publication
(10) Pub. No.: US 2004/0234093 A1
(43) Pub. Date: Nov. 25, 2004

(54) Sound output system

(75) Inventor: Fukushi Kawakami, Hamamatsu-shi (JP)

Correspondence Address: MORRISON & FOERSTER, LLP, 555 WEST FIFTH STREET, SUITE 3500, LOS ANGELES, CA, 90013-1024, US

(73) Assignee: YAMAHA CORPORATION, Hamamatsu-shi (JP)

(21) Appl. No.: 10/850,268

(22) Filed: May 19, 2004

(30) Foreign Application Priority Data
May 20, 2003 (JP) 2003-141767

(51) Int. Cl. H04R 1/02; H04R 9/06; H03G 3/00

(52) U.S. Cl. 381/335; 381/104; 381/103; 381/387

(57) ABSTRACT

Speaker device includes a main speaker unit and sub-speaker unit having their respective axes oriented in different directions. Signal processing device includes a processing unit for main speaker that supplies the main speaker unit with an, audio signal input to an input terminal, and a signal processing unit for sub-speaker including an adjustment section that adjusts a characteristic of the audio signal input to the input terminal. The signal processing unit for sub-speaker supplies the sub-speaker unit with the audio signal adjusted by the adjustment section.

### BACKGROUND OF THE INVENTION

The present invention relates to a technique for outputting audible sounds in accordance with signals indicative of sounds (hereinafter referred to as audio signals).

So far, there have been proposed various sound output systems for outputting sounds in accordance with audio signals, among which is one disclosed in Japanese Patent Application Laid-open Publication No. HEI-5-130689 (paragraph 0021 and FIG. 1 of the publication). FIG. 9 shows an example of the conventional sound output systems, which includes a signal processing device 91 and a speaker device 92. The signal processing device 91 includes, for example, an equalizer for increasing/decreasing a sound pressure level of each individual frequency constituent contained in an audio signal, a power amplifier for amplifying an, audio signal, and a section for adjusting characteristics of the audio signal. The speaker device 92 includes three speaker units 921 called a “tweeter”, “squawker” and “woofer”. Audio signal output from the signal processing device 91 is passed to a network 922, which divides the audio signal into three frequency constituents of different bands and supplies the divided frequency constituents to respective ones of the three speaker units 921.

Sounds generated by the speaker device 92 and heard by a human listener (or listeners) are classifiable broadly into sounds that reach the listener directly from the speaker device 92, i.e., without being reflected from any wall surface of a listening room (hereinafter referred to as “direct sounds”), and sounds that reach the listener indirectly from the speaker device 92 after being reflected from any wall surface of the listening room (hereinafter referred to as “indirect sounds”). With the conventional construction of FIG. 9, direct and indirect sounds are adjusted collectively because characteristics of each audio signal are adjusted in a collective fashion by the signal processing device 91. Thus, the conventional construction of FIG. 9 would suffer from the problem that it can not always properly adjust the characteristics of sounds to be output from the speaker device 92. The problem will be described more fully in relation to more specific examples.

FIG. 10A is a graph illustrating frequency characteristics of sounds output from the speaker device 92 of FIG. 9 and then heard by the listener. In FIG. 10A and other figures of subsequent figure numbers, there are shown a frequency characteristic of direct sounds (hereinafter “axial characteristic”) SPL1 and a frequency characteristic of a combination or sum of all direct and indirect sounds (hereinafter “steady-state transmission characteristic”) SPL0. In general, the direct sound has significant influences on a sound color and sound image auditorily perceived by the listener, and thus it is desirable that the axial characteristic SPL1, i.e. characteristic of the direct sound be substantially uniform over wide frequency bands as illustratively shown in FIG. 10A. As regards the steady-state transmission characteristic SPL0, there may occur regions of lower sound levels (hereinafter referred to as “dips”) D at and near crossover frequencies, corresponding to boundaries between the frequency bands allocated to the individual speaker units 921, than in other frequency bands. It is possible to adjust the steady-state transmission characteristic SPL0 to be substantially uniform as illustrated in FIG. 10B, by using an equalizer and the like of the signal processing device 91 to raise the levels of frequency constituents of the audio signal that correspond to the dips D. However, such an adjustment would undesirably influence the axial characteristic SPL1 as well. Namely, as seen in FIG. 10B, the axial characteristic SPL1 may present regions of higher sound levels (hereinafter referred to as “peaks”) P at and near the crossover frequencies than in other frequency bands. Direct sounds having such a characteristic would become offensive to the ear of the listener.

FIG. 11A is a graph showing an axial characteristic. SPL1 and steady-state transmission characteristic SPL0 where the speaker device 92 is located at a relatively great distance from the listener. Similarly to the illustrated example of FIG. 10A, the illustrated example of FIG. 11A assumes an audio signal adjusted to allow the axial characteristic SPL1 to be substantially uniform over wide frequency bands. The relatively great distance from the speaker device 92 to the listener would make it difficult for high frequency constituents of an indirect sound, in particular, to reach the listener. Thus, as regards the steady-state transmission characteristic SPL0, higher frequency bands would have lower sound levels, as illustrated in FIG. 11A. If the sound levels of high frequency constituents of the audio signal is increased via the signal processing device 91 in order to remove the sound level non-uniformity, then the sound levels of the high frequency constituents in the axial characteristic SPL1 would become greater than the sound levels of the other frequency bands. Direct sounds having such non-uniform sound levels would become offensive to the ear of the listener, as in the case of FIG. 10B.

Namely, with the conventional technique, where the direct and indirect sounds are adjusted in interlocked relation to each other as set forth above, there would arise the problem that both the axial characteristic SPL1 and the steady-state transmission characteristic SPL0 can not be adjusted as desired.

### SUMMARY OF THE INVENTION

In view of the foregoing, it is an object of the present invention to provide an improved sound output system which can adjust characteristics of sounds to be heard by a human listener more appropriately than the conventionally-known techniques.

In order to accomplish the above-mentioned object, the present invention provide a sound output system, which comprises: a first sounding section that outputs an audible sound corresponding to a supplied audio signal; a second sounding section that outputs an audible sound corresponding to a supplied audio signal, the second sounding section having a sound axis oriented differently (in a different direction) from a sound axis of the first sounding section; a first signal processing section that supplies the first sounding section with an audio signal input to an input terminal; and a second signal processing section including an adjustment section that adjusts a characteristic of the audio signal inputted to the input terminal, the second signal processing section supplying the second sounding section with the audio signal adjusted by the adjustment section.

Stated differently, the sound output system of the invention comprises: a first sounding section that outputs an audible sound corresponding to a supplied audio signal; a second sounding section that outputs an audible sound corresponding to a supplied audio signal, the second sounding section having a sound axis oriented differently from a sound axis of the first sounding section; and a signal processing section that supplies the first and second sounding sections with an audio signal inputted to an input terminal, the signal processing section including an adjustment section that adjusts a characteristic of the audio signal to be supplied to the second sounding section independently of the audio signal to be supplied to the first sounding section.

According to the present invention, where the sound axis of the second sounding section is oriented in a different direction from the sound axis of the first sounding section, the characteristic of the sound to be sounded (i.e., audibly produced) from the second sounding section is adjusted independently of the sound to be sounded by the first sounding section. Thus, where the sound output system is arranged, for example, in such a manner that the sound audibly produced from the first sounding section is caused to be heard as a direct sound by a human listener while the sound audibly produced from the second sounding section is caused to be heard as an indirect sound by the human listener, the characteristic of the indirect sound can be adjusted without the characteristic of the direct sound being influenced by the adjustment. In more specific terms, the present invention can adjust a power response as desired without influencing an axial characteristic SPL1. The “power response” represents frequency characteristics of a combination of all energy radiated in all directions from the sound output system due to the audible sound production by the first and second sounding sections. Because a steady-state transmission characteristic SPL0 varies in accordance with the power response, it may be said that the present invention can adjust the steady-state transmission characteristic SPL0 without influencing the steady-state transmission characteristic SPL0.

Note that the terms “sound axis” are used herein to refer to an axis extending frontward from a speaker (sounding section). To give some specific examples, where a cone-shaped speaker unit is used as the sounding section, the central axis of the cone corresponds to the sound axis, where a horn-shaped speaker unit is used as the sounding section, the central axis of the horn corresponds to the sound axis, and where a dome-shaped speaker unit is used as the sounding section, the central axis of the dome corresponds to the sound axis. In other words, with a speaker unit constructed to produce audible sounds through vibration of an electric conductor positioned in a magnetic field, the central axis of a cylindrically-formed voice coil corresponds to the sound axis of the speaker.

It should also be appreciated that the adjustment section employed in the inventive sound output system may be arranged to adjust the characteristic of the audio signal in accordance with an instruction given by a user (e.g., listener) or on the basis of a pre-defined algorithm. In the latter case (where the algorithm-based adjustment is used), the characteristic of the audio signal may be adjusted so that the sound pressure levels of both of the direct and indirect sounds to be heard by the listener can be made uniform over wide frequency bands.

The following will describe embodiments of the present invention, but it should be appreciated that the present invention is not limited to the described embodiments and various modifications of the invention are possible without departing from the basic principles of the invention. The scope of the present invention is therefore to be determined solely by the appended claims.

### BRIEF DESCRIPTION OF THE DRAWINGS

For better understanding of the object and other features of the present invention, its preferred embodiments will be described hereinbelow in greater detail with reference to the accompanying drawings, in which:

FIG. 1 is a block diagram illustrating an overall setup of a sound output system in accordance with an embodiment of the present invention;

FIGS. 2A and 2B are views illustrating construction of a speaker device in the embodiment of FIG. 1;

FIGS. 3A and 3B are diagrams explanatory of benefits achievable by the embodiment;

FIGS. 4A and 4B are diagrams explanatory of benefits achievable by the embodiment;

FIG. 5 is a block diagram illustrating a setup of a sound output system in accordance with a modified example of the present invention;

FIG. 6 is a block diagram illustrating a setup of a sound output system in accordance with another modified example of the present invention;

FIG. 7 is a block diagram illustrating a setup of a sound output system in accordance with still another modified example of the present invention;

FIG. 8A is a block diagram illustrating a setup of a sound output system in accordance with still another modified example of the present invention, and FIG. 8B is a front view of a speaker device employed in the modified example of FIG. 8A;

FIG. 9 is a block diagram showing a conventional sound output system;

FIGS. 10A and 10B are graphs explanatory of inconveniences encountered by the conventional sound output system; and

FIGS. 11A and 11B are also graphs explanatory of inconveniences encountered by the conventional sound output system.

### DETAILED DESCRIPTION OF THE INVENTION

A. Setup of Sound Output System:

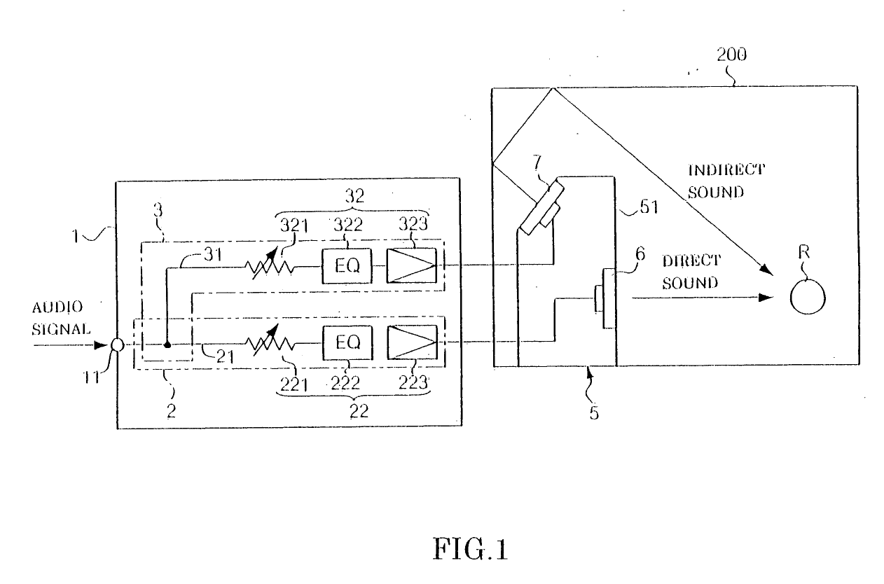

FIG. 1 is a block diagram illustrating an overall setup of a sound output system in accordance with an embodiment of the present invention. As shown, this sound output system includes a signal processing device 1 and a speaker device 5. The signal processing device 1 is a means for processing each audio signal supplied from a higher-order device (not shown) and outputting the resultant processed audio signal to the speaker device 5. For example, the higher-order device may be a disk reproduction device for outputting audio signals on the basis of data read out from any one of various recording media, such as an optical disk or magnetic disk, a tone generator device for generating audio signals on the basis of data compliant with the MIDI (Musical Instrument Digital Interface) standards, or a microphone for outputting audio signals by picking up ambient sounds. The speaker device 5, on the other hand, is a means for outputting audible sounds corresponding to the audio signal supplied from the signal processing device 1, which is installed on a floor surface of a listening room 200. Human listener R in the listening room 200 can hear the sounds output from the speaker device 5.

The speaker device 5 includes a main speaker unit (first sounding section) 6, a sub-speaker unit (second sounding section) 7, and a cabinet (housing) 51 accommodating these speaker units 6 and 7. The main speaker unit 6 and sub-speaker unit 7 may each comprise any desired one of conventionally-known speaker units, such as cone-shaped, horn-shaped and dome-shaped speakers. Namely, the speaker units 6 and 7 may be constructed in any desired manner as long as they are capable of outputting audible sounds corresponding to audio signals.

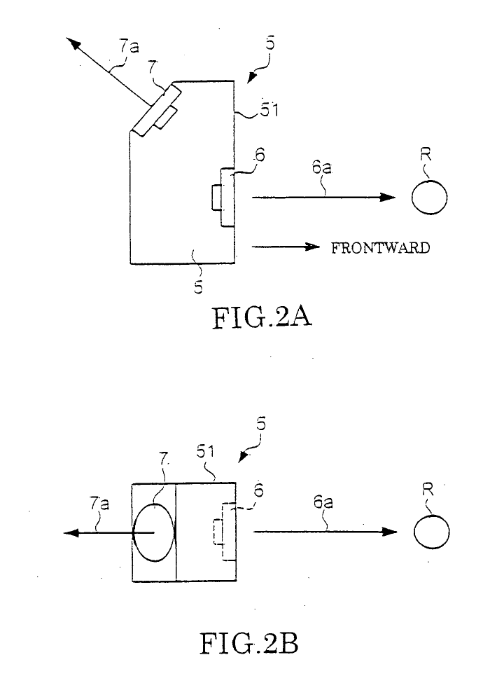

FIGS. 2A and 2B show example construction of the speaker device 5 with a particular focus on sound axis orientations of the individual speakers. Specifically, FIG. 2A is a side view of the speaker device 5, while FIG. 2B is a top plan view of the speaker device 5. As shown, the main speaker unit 6 is positioned in the cabinet 51 in such a manner that its sound axis 6a is oriented to extend practically straight to the listener R, i.e. that the listener R is located on the sound axis 6a. Therefore, at least part of a sound audibly produced from the main speaker unit 6 can be heard by the listener as a direct sound without being reflected from any wall surface of the listening room 200, as clearly seen in FIG. 1. On the other hand, the sub-speaker unit 7 is positioned in the cabinet 51 in such a manner that its sound axis 7a is oriented in a different direction from the sound axis 6a of the main speaker unit 6. More specifically, the sound axis 7a of the sub-speaker unit 7 is oriented in an opposite direction from the sound axis 6a of the main speaker unit 6 as the speaker device 5 is viewed in a vertical direction (i.e., from above) as seen in FIG. 2B, and oriented to extend higher than the sound axis 6a of the main speaker unit 6 as the speaker device 5 is viewed in a horizontal direction. (i.e., sideways) as seen in FIG. 2A. Therefore, a sound produced from the sub-speaker unit 7 will be heard by the listener R as an indirect sound after being reflected from the wall surface of the listening room one or more times, as seen in FIG. 1. Stated differently, the orientation of the sound axis 7a of the sub-speaker unit 7 is determined such that each sound output from the sub-speaker unit 7 can be heard by the listener R as an indirect sound.

The signal processing device 1 of FIG. 1, on the other hand, includes a processing unit for main speaker 2 and a processing unit for sub-speaker 3. The processing unit for main speaker 2 is a means for supplying an audio signal, input from the higher-order device to an input terminal 11, to the main speaker unit 6, which, for this purpose, has a transfer line 21 extending from the input terminal 11 to the main speaker unit 6. The processing unit for sub-speaker 3 is a means for supplying the audio signal, input from the higher-order device to the input terminal 11, to the sub-speaker unit 7, which, for this purpose, has a transfer line 31 branching off from the main-speaker transfer line 21 to the sub-speaker unit 7.

The processing unit for sub-speaker 3 includes an adjustment section 32 for adjusting characteristics of an audio signal to be supplied to the sub-speaker unit 7. The adjustment section 32 includes a volume control 321 for adjusting a sound pressure level of the audio signal, an equalizer 322 for adjusting sound pressure levels of individual frequency constituents of the audio signal that belong to a predetermined frequency band, and a power amplifier 323 for amplifying the audio signal to thereby output the amplified audio signal to the sub-speaker unit 7. Similarly, the processing unit for main speaker 2 includes a volume control 221, equalizer 222 and power amplifier 223 as an adjustment section 22 for adjusting characteristics of an audio signal to be supplied to the main speaker unit 6.

Further, the signal processing device 1 includes an input device (not shown) including various operators, such as knobs and buttons. The details of the adjustment performed by the adjustment sections 22 and 32 on the audio signal are determined in accordance with the content of user's operation performed via the input device.

With such arrangements, the audio signal input via the input terminal 11 to the transfer line 21 is subjected to the characteristic adjustment by the adjustment section 22 and then output as an audible sound from the main speaker unit 6. The sound thus output from the main speaker unit 6 is heard as an indirect sound by the listener R.

Namely, in the instant embodiment, characteristics of each audio signal to be supplied to the sub-speaker unit 7, which outputs an indirect sound, are adjusted independently of each audio signal to be supplied to the main speaker unit 6. In this way, characteristics of the indirect sound that reaches the listener R indirectly from the sub-speaker unit 7 can be adjusted without influencing characteristics of the direct sound that reaches the listener R directly from the main speaker unit 6. In other words, the instant embodiment can adjust a power response in a desired manner without influencing an axial characteristic SPL1. Here, the terms “power response” refer to frequency characteristics of a sum of all energy radiated in all directions from the speaker device 5 due to the sound production by the speaker device 5. Steady-state transmission characteristic SPL0, which represents frequency characteristics of a sum of all direct and indirect sounds, is influenced by the power response. Therefore, with the instant embodiment, it is possible to uniformly adjust the steady-state transmission characteristic SPL0 over wide frequency bands without influencing the axial characteristic SPL1, as will be detailed hereinbelow.

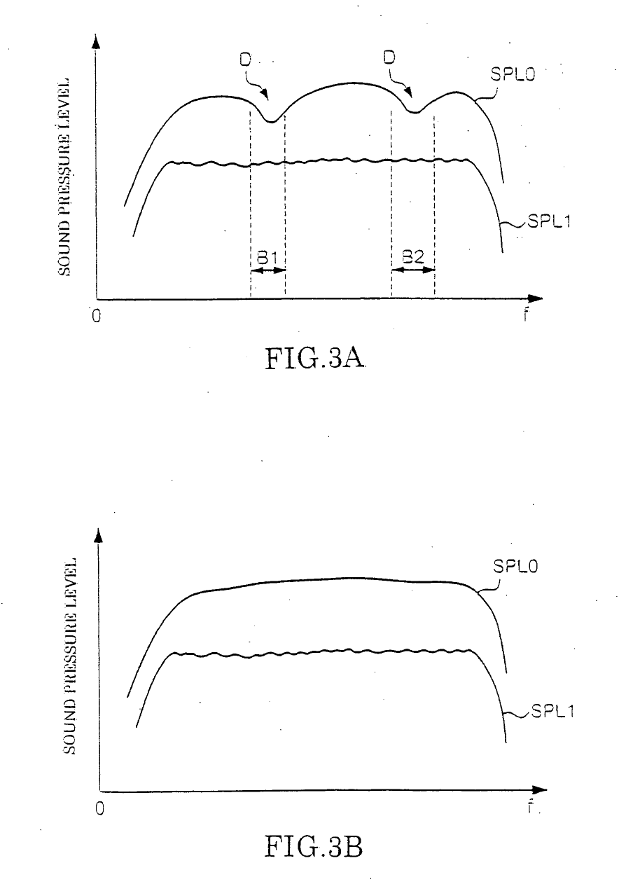

Let's now assume a case where the axial characteristic SPL1 and steady-state transmission characteristic SPL0 of an audible sound output from the speaker device 5 and heard by the listener R are just as illustrated in FIG. 3A, e.g., where the speaker device 5 and the listener R are spaced apart from each other with a relatively small distance in a narrow or small acoustic space. Namely, the case assumed here is where the axial characteristic SPL1 is uniform over wide frequency bands while the steady-state transmission characteristic SPL0 has dips D in given frequency bands B1 and B2. In this case, the steady-state transmission characteristic SPL0 can be adjusted to be substantially uniform over wide frequency bands as illustrated in FIG. 3B, if, of the audio signal to be supplied to the sub-speaker unit 7, the sound pressure levels of frequency constituents belonging to the frequency bands B1 and B2 are increased appropriately. Because the direct sound to be output from the main speaker unit 6 is not influenced at all during that time, both the axial characteristic SPL1 and the steady-state transmission characteristic SPL0 can be made uniform over wide frequency bands as illustrated in FIG. 3B.

In reproduction of a rhythmical music piece, such as rock or pop music, direct sounds become a particularly important factor that determines an impression of a sound perceived by the listener R. By contrast, in reproduction of a music piece performed on an organ, classical music piece or the like, indirect sounds become a particularly important factor that determines an impression of a sound perceived by the listener R. With the instant embodiment, where both the axial characteristic SPL1 of direct sounds and the steady-state transmission characteristic SPL0 of indirect sounds can be made uniform over wide frequency bands, it is possible to effectively avoid undesired differences in sound color balance perceived by the listener R even where music pieces of different melodies or tunes, such as rhythmical and classical music pieces, are reproduced. Further, the instant embodiment can achieve hi-fi reproduction of natural sounds with realism, by improving connection between sounds to be output from the plurality of speaker units having different frequency bands allocated thereto, i.e. by eliminating the dips D at and near the crossover frequencies.

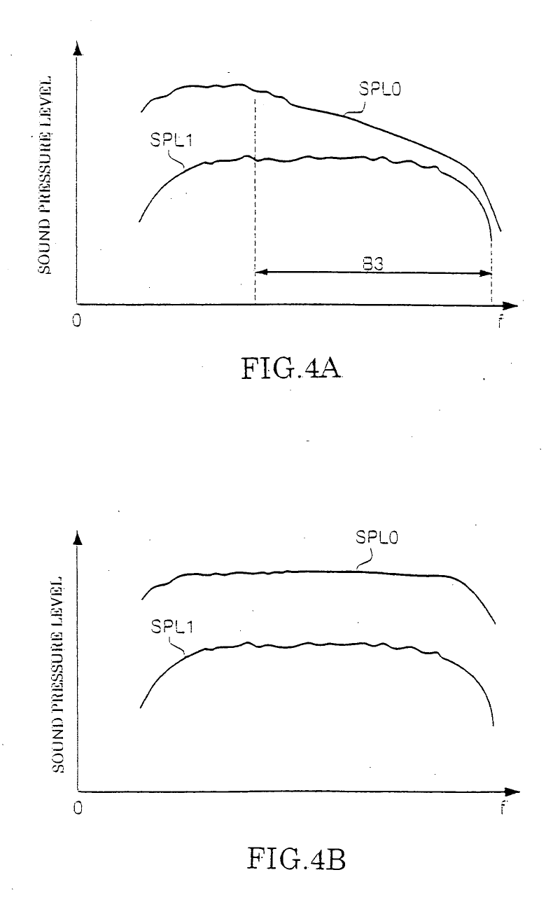

FIG. 4A shows an exemplary axial characteristic SPL1 and steady-state transmission characteristic SPL0 in a case where the speaker device 5 and the listener R are spaced apart from each other with a relatively great distance (e.g., in a large acoustic space, such as a church or auditorium). As shown, the axial characteristic SPL1 in this case is uniform over wide frequency bands while the steady-state transmission characteristic SPL0 presents a sound level curve lowering as the frequency becomes higher. This is because the indirect sound tends to be easily attenuated, particularly in its high frequency constituents, due to absorption by air and the like over a long transmission path to the listener R. In such a case, the steady-state transmission characteristic SPL0 can be adjusted to be substantially uniform over wide frequency bands as illustrated in FIG. 4B, if, of the audio signal to be supplied to the sub-speaker unit 7, the sound pressure levels of frequency constituents belonging to a frequency band B3 are increased appropriately. Because such adjustment of the steady-state transmission characteristic SPL0 would not have any influence on characteristics of the direct sound to be output from the main speaker unit 6, the axial characteristic, SPL1 too can be kept uniform over wide frequency bands, as illustrated in FIG. 4B.

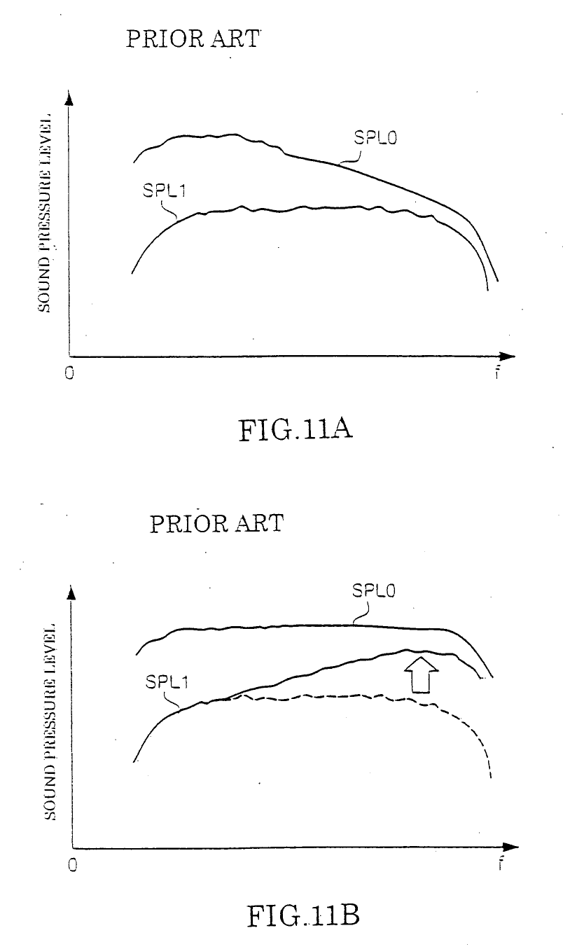

In a large acoustic space or the like where the distance between the speaker device 5 and the listener R is relatively great, characteristics of a wave front of a sound produced from the speaker device 5 to first reach the listener R (first wave front), i.e. characteristics of a direct sound become an important factor that determines an impression of the sound to be perceived by the listener R. This is because, in a large acoustic space, it takes a longer time for an indirect sound to reach the listener R after arrival, at the listener R, of the direct sound than in a small acoustic space. Therefore, if the uniformity of the axial characteristic SPL1 is lost, as illustrated in FIG. 11, due to adjustment of the steady-state transmission characteristic SPL0 in such a large acoustic space, then the listener would get an unnatural impression of the sound produced from the speaker device. By contrast, the instant embodiment can provide a sound full of reverberations by adjusting the steady-state transmission characteristic SPL0 to be uniform independently of the axial characteristic SPL1, and it can also effectively prevent the impression of the sound from being varied due to the adjustment. Stated differently, in the case where the speaker device 5 of the instant embodiment is installed in a large acoustic space, it is possible to improve influences which a sound produced from the speaker device 6 has on the auditory sense of the listener in a time domain.

Further, with the instant embodiment, it is possible to vary, as desired, sound pressure level balance between the direct sound output from the main speaker unit 6 to the listener R and the indirect sound output from the sub-speaker unit 7 to the listener R. As a consequence, the instant embodiment can appropriately vary the reverberation of each sound to be perceived by the listener R. For example, adjusting the volume control 321 of the sub-speaker unit 7 can increase the sound pressure level of the indirect sound (namely, reverberant sound) produced from the sub-speaker unit 7 and indirectly reaching the listener R after being reflected from a wall surface of the sub-speaker unit 7, and thus the adjustment can increase the reverberation to be perceived by the listener R. Conversely, in order to decrease the reverberation to be perceived by the listener R, it suffices to merely lower the sound pressure level of the indirect sound produced from the sub-speaker unit 7 and reaching the listener R indirectly from the unit 7, by adjusting the volume control 321 of the sub-speaker unit 7. Generally, the characteristics of the indirect sound heard by the listener R as a reverberant sound are influenced by various conditions, such as sound absorption characteristics of wall surfaces of the listening room 200, volume capacity of the listening room 200 and distance from the speaker device 5 to the listening room R, but the instant embodiment can appropriately adjust these conditions by adjusting the sound pressure level balance between the direct and indirect sounds.

B. Modification:

The above-described embodiment is merely for illustrative purposes, and the present invention may be modified variously without departing from the basic principles of the invention. The following are some possible examples of various modifications.

B-1. Modification 1:

The adjustment sections 22 and 32 and the main speaker unit 6 and sub-speaker unit 7 employed in the above-described embodiment may be modified as follows.

(1) First Form of Modification 1:

In the above-described embodiment, the volume control 221 and equalizer 222 are included in the processing unit for main, speaker 2 that supplies an audio signal to the main speaker unit 6. Thus, even where the axial characteristic SPL1 presents dips or peaks, the described embodiment can adjust the axial characteristic SPL1 to be uniform over wide frequency bands, by causing the volume control 221 or equalizer 222 to operate as appropriate. However, where the main speaker unit 6 itself is constructed in advance in such a manner that the axial characteristic SPL1 can be made flat over wide frequency bands, the volume control 221 and equalizer 222 can be dispensed with.

(2) Second Form of Modification 1:

In the above-described embodiment, the equalizers 222 and 322 are included in the signal processing device 1. However, where only sound pressure level balance between direct and indirect sounds is to be adjusted, the equalizers 222 and 322 may be dispensed with as illustrated in FIG. 6. Note that, in the illustrated example of FIG. 6, a passive network 75 is provided at a stage preceding the sub-speaker unit 7. The passive network 75 functions as a filter for selectively outputting only constituents of an audio signal that belong to a given frequency band. Even without the equalizer 322, such arrangements can raise the sound levels of the constituents of an indirect sound that belong to the pass band of the passive network 75 and thereby appropriately adjust the steady-state transmission characteristic SPL0.

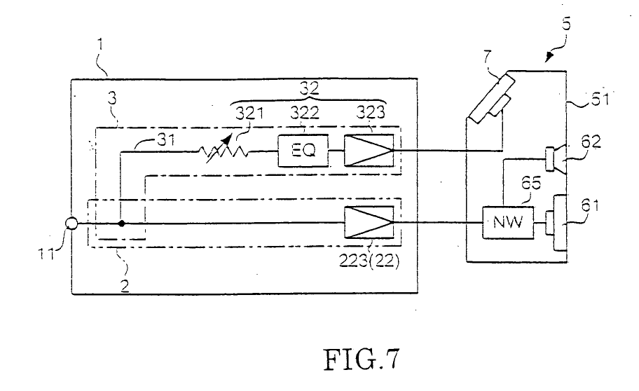

(3) Third Form of Modification 1:

Whereas the preferred embodiment has been described as having only one speaker unit (main speaker unit 6) with its sound axis oriented to extend substantially straight to the listener R, there may be provided a plurality of such speaker units. Namely, as illustratively shown in FIG. 7, the main speaker unit 6 of FIG. 1 may be replaced with a combination of a passive network. 65, first main speaker unit 61 and second main speaker unit 62. The passive network 65 is a means for dividing an audio signal, supplied from the processing unit for main speaker 2, into two frequency constituents of different bands. While an audio signal of one of the two frequency constituents lower in frequency than the other frequency constituents (i.e., lower frequency constituent) is supplied to the first main speaker unit 61, an audio signal of the higher frequency constituent is supplied to the second main speaker unit 62. Such arrangements allow the first main speaker unit 61 to function as a woofer and the second main speaker unit 62 to function as a tweeter. Needless to say, three or more main speaker units, rather than two, may be employed, in which case the passive network 65 is arranged to divide each audio signal into a specific number of frequency constituents that is identical to or smaller than the number of the main speaker units.

(4) Fourth Form of Modification 1:

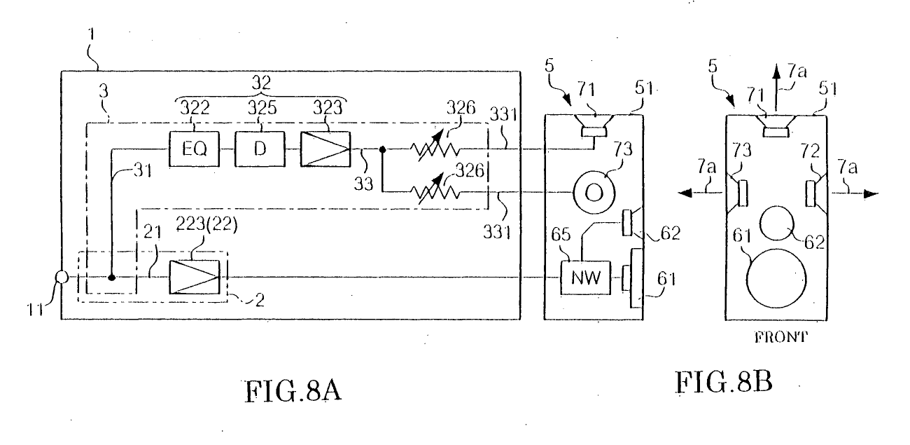

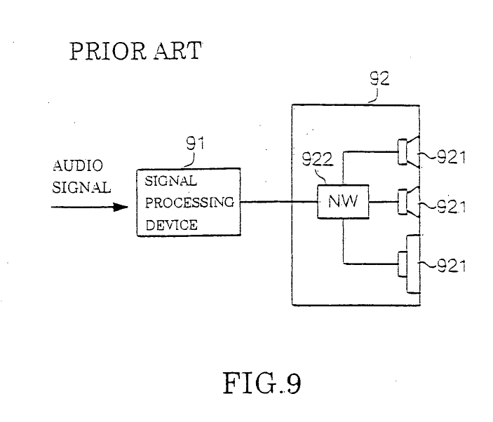

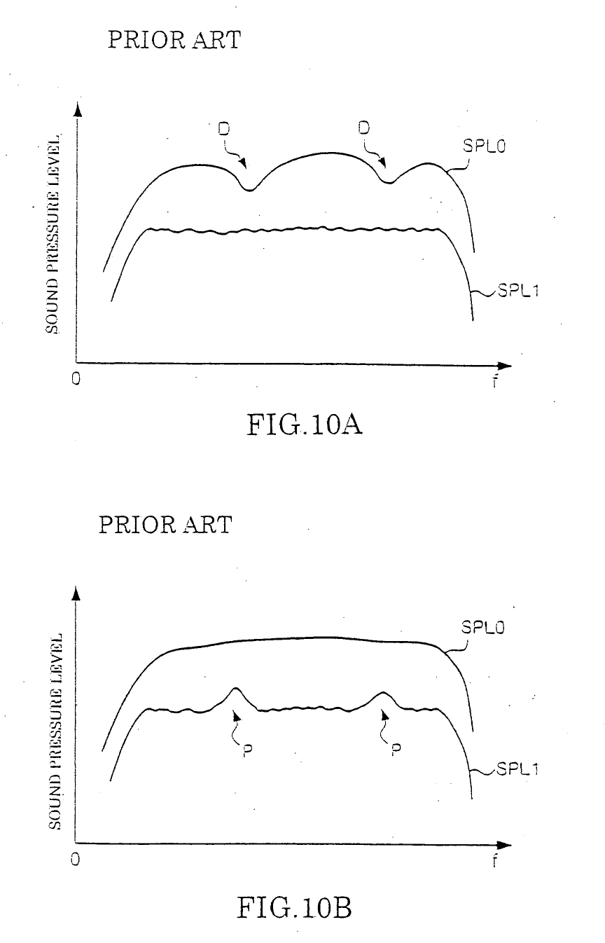

Means for delaying an audio signal may be included in the adjustment section 32 of the processing unit for sub-speaker 3. FIG. 8A is a block diagram showing a setup of this form of modification, where two main speakers 61 and 62 and passive network 65 are provided as in the illustrated example of FIG. 7.

As illustrated in FIG. 8A, this form of modification includes a delay section 325 provided between the equalizer 322 and the power amplifier 323 in the adjustment section 32 of the processing unit for sub-speaker 3. The delay element 325 is a means for delaying an audio signal output from the equalizer 322 and supplying the thus-delayed audio signal to the power amplifier 323. Specifically, the delay element 325 may be in the form of an FIR filter or the like. The delay time to be provided by the delay element 325 may be varied, as appropriate, by the user operating the input device.

FIG. 8B is a front view of the speaker device 5 shown in FIG. 8A. As illustrated in FIGS. 8A and 8B, the sub-speaker unit 7 of FIG. 1 is replaced with three speaker units: first sub-speaker unit 71, second sub-speaker unit 72 and third sub-speaker unit 73. Of the three speaker units, the first sub-speaker unit 71 is oriented so that its sound axis 7a extends vertically upward. As illustrated in FIG. 8B, the second sub-speaker unit 72 is oriented so that its sound axis 7a extends horizontally rightward as the speaker device 5 is viewed head-on. The third sub-speaker unit 73 is oriented so that its sound axis 7a extends horizontally leftward as the speaker device 5 is viewed head-on. Namely, the respective orientations of the first to third sub-speaker units 71 to 73 are set such that, when the speaker device 5 is installed so that the individual surfaces of the cabinet 51 having a substantial parallelepiped shape lie parallel to the corresponding wall surfaces of the listening room 200, the respective sound axes 7a of the first to third sub-speaker units 71 to 73 lie perpendicularly to the wall surfaces of the listening room 200. Transmission line 33, over which an audio signal is output from the power amplifier 323 of the processing unit for sub-speaker 3, branches into three lines 331, and these branched transmission lines 331 are coupled to the first to third sub-speaker units 71 to 73, respectively. Further, in this modification, the volume 321 of FIG. 1 is replaced with volume controls 326 provided on the branched transmission lines 331, so that the sound levels of the audio signals to be supplied to the sub-speaker units 71 to 73 can be adjusted independently of one another. Any desired number of the sub-speaker units, rather than just three, may be provided.

With the above-described arrangements, each sound to be heard by the listener R can be adjusted to approach a sound that is actually heard in any of various acoustic spaces having different shapes, sizes, etc. For example, if the delay time to be provided by the delay element 325 is adjusted to be longer, it is possible to prolong the time length from the time when sounds output from the main speaker units 61 and 62 are heard as direct sounds by the listener R to the time when sounds output from the sub-speaker units 71 to 73 are heard as indirect sounds by the listener R. Thus, the listener R in the listening room 200 is allowed to experience auditory effects similar to those achievable in a large space where an audibly produced sound reaches a listener after having traveled a long distance. Further, if the sound pressure levels of sounds to be output from the second and third sub-speaker units 72 and 73, having their respective sound axes 7a lying horizontally, are increased, then the sound levels of indirect sounds reaching the listener in the horizontal direction can be increased. Thus, the listener R is allowed to experience a feeling of being surrounded with the sounds. In this manner, this modification can control, as appropriate, acoustic effects to be perceived by the listener R.

(5) Other form of Modification 1:

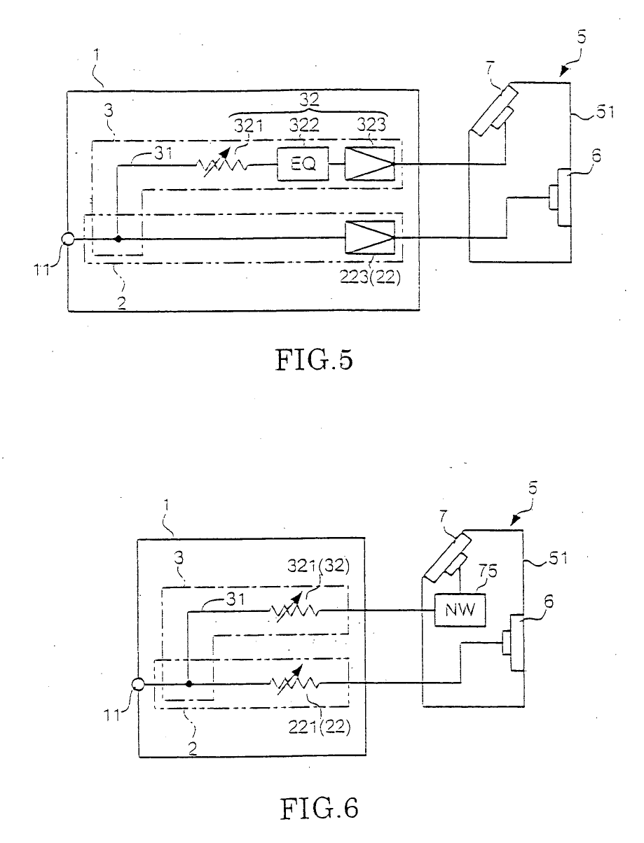

The adjustment sections 22 and 32 in the signal processing device 1 may be constructed in any other desired manner than the above-described. For example, the adjustment sections 22 and 32 may each include an attenuator in place of, or in addition to, the volume control 221 or 321, and/or various kinds of filters. Further, the arrangements shown in FIG. 1 as the preferred embodiment of the invention, and the arrangements shown in FIGS. 5 to 8 as the first to forth forms of modification may be combined as appropriate.

B-2. Modification 2:

Whereas the preferred embodiment and modifications have been described above as arranged in such a manner that the details of the adjustment by the adjustment sections 22 and 23 are determined in accordance with operation by the listener R or user, the present invention may be arranged to determine the details of the adjustment on the basis of any other suitable condition. For example, the details of the adjustment by the equalizer 322 shown in FIG. 1, such as a frequency band for which the sound pressure level adjustment is to be performed and adjustment amount of the sound pressure level, may be determined such that the steady-state transmission characteristic SPL0 can be made uniform over wide frequency bands, i.e. that the sound levels of direct and indirect sounds to be heard by the listener R can be made substantially uniform.

B-3. Modification 3:

Whereas the preferred embodiment and modifications have been described above in relation to the case where the signal processing device 1 and speaker device 5 are provided separately, these devices 1 and 5 may be accommodated together as an integral device in the cabinet 51. Further, a part of (i.e., one or more, but not all, of the components of the signal processing device 1 may be included in the speaker device 5, and similarly a part of the speaker device 5 may be included in the signal processing device 1.

In summary, the present invention arranged in the above-described manner can adjust characteristics of sounds to be heard by the listener, more appropriately than the conventionally-known techniques.

What is claimed is:

1. A sound output system comprising:
a first sounding section that outputs an audible sound corresponding to a supplied audio signal;
a second sounding section that outputs an audible sound corresponding to a supplied audio signal, said second sounding section having a sound axis oriented differently from a sound axis of said first sounding section;
a first signal processing section that supplies said first sounding section with an audio signal inputted to an input terminal; and
a second signal processing section including an adjustment section that adjusts a characteristic of the audio signal inputted to the input terminal, said second signal processing section supplying said second sounding section with the audio signal adjusted by said adjustment section.

2. A sound output system as claimed in claim 1 wherein said adjustment section includes a volume control that adjusts a sound pressure level indicated by the audio signal.

3. A sound output system as claimed in claim 1 wherein said adjustment section includes an equalizer that adjusts a sound pressure level of the audio signal for each frequency constituent that belongs to a given frequency band.

4. A sound output system as claimed in claim 1 wherein said adjustment section includes a delay section that delays the audio signal.

5. A sound output system as claimed in claim 1 wherein said second sounding section includes a plurality of speaker units, each of said speaker units having a sound axis oriented in a substantial horizontal or vertical direction.

6. A sound output system as claimed in claim 1 wherein said first sounding section is positioned so that the sound axis thereof is oriented to extend to a listener, and
said second sounding section is positioned so that the sound axis thereof is oriented oppositely from the sound axis of said first sounding section as viewed in a vertical direction and oriented to extend higher than the sound axis of said first sounding section.

7. A sound output system as claimed in claim 1 wherein said first sounding section includes:
a division section that outputs the supplied audio signal as a plurality of frequency constituents belonging to different frequency bands; and
a plurality of speaker units that outputs audible sounds corresponding to the plurality of frequency constituents outputted by said division section.

8. A sound output system as claimed in claim 1 wherein said first signal processing section includes an adjustment section that adjusts a characteristic of the audio signal inputted to the input terminal, and said first signal processing section supplies said first sounding section with the audio signal adjusted by said adjustment section.

9. A sound output system comprising:
a first sounding section that outputs an audible sound corresponding to a supplied audio signal;
a second sounding section that outputs an audible sound corresponding to a supplied audio signal, said second sounding section having a sound axis oriented differently from a sound axis of said first sounding section; and
a signal processing section that supplies said first and second sounding sections with an audio signal inputted to an input terminal, said signal processing section including an adjustment section that adjusts a characteristic of the audio signal to be supplied to said second sounding section independently of the audio signal to be supplied to said first sounding section.

10. A sound output system as claimed in claim 9 wherein said adjustment section includes a volume control that adjusts a sound pressure level indicated by the audio signal.

11. A sound output system as claimed in claim 9 wherein said adjustment section includes an equalizer that adjusts a sound pressure level of the audio signal for each frequency constituent that belongs to a given frequency band.

12. A sound output system as claimed in claim 9 wherein said adjustment section includes a delay section that delays the audio signal.

13. A sound output system as claimed in claim 9 wherein said second sounding section includes a plurality of speaker units, each of said speaker units having a sound axis oriented in a substantial horizontal or vertical direction.

14. A sound output system as claimed in claim 9 wherein said first sounding section is positioned so that the sound axis thereof is oriented to extend to a listener, and
said second sounding section is positioned so that the sound axis thereof is oriented oppositely from the sound axis of said first sounding section as viewed in a vertical direction and oriented to extend higher than the sound axis of said first sounding section.

15. A sound output system as claimed in claim 9 wherein said first sounding section includes:
a division section that outputs the supplied audio signal as a plurality of frequency constituents belonging to different frequency bands; and
a plurality of speaker units that outputs audible sounds corresponding to the plurality of frequency constituents outputted by said division section.
